(19) United States
(12) Patent Application Publication
(10) Pub. No.: US 2026/0018379 A1
(43) Pub. Date: Jan. 15, 2026

(54) BEAM TUNING FOR NON-UNIFORM ION IMPLANTATION

(71) Applicant: Applied Materials, Inc., Santa Clara, CA (US)

(72) Inventors: Morgan Evans, Manchester, MA (US); Tyler WILLS, Marblehead, MA (US); Jeffrey Morse, Center Tuftonboro, NH (US)

(73) Assignee: Applied Materials, Inc., Santa Clara, CA (US)

(21) Appl. No.: 19/211,869

(22) Filed: May 19, 2025

Related U.S. Application Data
(60) Provisional application No. 63/670,319, filed on Jul. 12, 2024.

(51) Int. Cl. H01J 37/317; H01J 37/304

(52) U.S. Cl. CPC H01J 37/3171; H01J 37/304; H01J 2237/20214; H01J 2237/20228; H01J 2237/24528; H01J 2237/24535; H01J 2237/30483; H01J 2237/31703

(57) ABSTRACT

A method of producing a non-uniform ion implant in a workpiece, including storing a target pattern as a target pattern array, analyzing the target pattern to identify maximal gradients, rotating the target pattern and the workpiece to align with a spot beam profile and a scan direction, and transposing the target pattern to a process array. The method further includes optimizing the process array, calculating a largest possible beam spot size, selecting a corresponding spot beam recipe, performing a test scan to determine a beam sweep angle of the spot beam, and rotating the target pattern, the process array, and the workpiece to account for the beam sweep angle. The method further incudes generating a predicted process dose pattern and comparing it to the target pattern, and calculating at least one measure of error representing a fidelity of the predicted process dose pattern to the target pattern.

### FIELD OF THE DISCLOSURE

Embodiments of the present disclosure relate to a system and method for controlling a scanned spot beam, and more particularly to a scanned beam ion implanter.

### BACKGROUND OF THE DISCLOSURE

Various types of ion sources may be used to generate ions that are used in semiconductor manufacturing processes. For example, an ion source may be adapted to generate a so-called “spot beam.” A spot beam is an ion beam in which ions are projected as a beam having a generally circular (though sometimes ellipsoid, oblong, or irregular) cross-sectional shape and cross-sectional size that is significantly smaller than a surface area of a workpiece onto which the spot beam is projected. A spot beam may be projected through an electrostatic scanner adapted to controllably deflect the spot beam at varying angles in a first direction. For example, an electrostatic scanner may deflect the spot beam in a horizontal direction. The amount of deflection may be sufficient to scan the spot beam across the entire diameter of a workpiece that is being processed by the spot beam. Thus, the spot beam, which may have a width that is significantly smaller than a width of the workpiece, may be scanned horizontally across the workpiece to implant the entire width of the workpiece. Typically, a workpiece is disposed on a movable workpiece holder, which is movable in a second direction perpendicular to the first direction. For example, the workpiece holder may translate the workpiece in a vertical direction. In this way, the entirety of the workpiece may be processed by the spot beam. In other words, the spot beam may be deflected back and forth in the first direction (e.g., horizontally), while the workpiece is translated in the second direction (e.g., vertically).

In some applications, it may be desirable to implant a workpiece in a non-uniform or asymmetrical manner, wherein some portions of a workpiece are implanted more heavily than other portions. For example, if a workpiece exhibits warping, a stress management film formed of a material such as silicon nitride, silicon dioxide, various carbon-based materials, etc. may be applied to the wafer, and the film may be subjected to a non-uniform implant to introduce or relax mechanical stress in the film in a highly controlled, targeted manner intended to forcibly counteract the warping in the workpiece. This is but one example of an application of non-uniform implantation. Many others exist.

Achieving a desired, non-uniform ion implantation pattern using a spot beam is associated with certain challenges. One such challenge is non-uniformity of ion distribution as the spot beam is scanned in the first direction (e.g., in the horizontal direction). That is, properties of an ion beam may vary in an unintended and undesirable manner as a function of the position of the spot beam in the first direction. This may be due to non-uniformities in the electrostatic scanner. For example, as the spot beam is scanned across a workpiece, the height of the spot beam may shrink, and the centroid of the spot beam may shift (e.g., move downward). If these unintended variations are unaccounted for, a pattern that is ultimately implanted in a workpiece will vary from that which was intended.

A further challenge associated with achieving a desired, non-uniform ion implant pattern is that spot beams generally do not have perfectly circular cross-sectional shapes. Rather, spot beams typically have cross-sectional shapes that are ellipsoid, oblong, or irregular. In many cases, the shape of a particular spot beam may be ill-suited for achieving a desired, non-uniform ion implant pattern. For example, a portion of a desired, non-uniform implant pattern may call for implantation along a thin, horizontal line across a workpiece, whereas a spot beam may have a cross-sectional height that is greater than a height of the desired line.

In view of the above, it is desirable to provide a method for achieving a desired, non-uniform ion implantation dose pattern in a convenient and expeditious manner that optimizes throughput, maximizes setup success rate, and reduces material waste and downtime. With respect to these and other considerations, the present disclosure is provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A method of producing a non-uniform ion implant in a workpiece according to the present disclosure includes providing a target pattern to a system controller of a spot beam ion implantation system, wherein the system controller stores the target pattern as a target pattern array, analyzing the target pattern to identify locations and orientations of maximal gradients in the target pattern, and rotating the target pattern and the workpiece to align with a spot beam profile and a scan direction, and transposing the target pattern from the target pattern array to a process array. The method further includes optimizing properties of the process array to better suit the target pattern, calculating a largest possible beam spot size appropriate for reproducing the target pattern, and selecting a spot beam recipe for producing an optimal spot beam adapted to reproduce the target pattern during an implantation process. The method further includes performing a test scan, wherein a spot beam is generated according to the spot beam recipe and is scanned across a beam profiler of the spot beam ion implantation system to determine a beam sweep angle of the spot beam, and rotating the target pattern, the process array, and the workpiece to account for the beam sweep angle. The method further includes generating a predicted process dose pattern, comparing the predicted process dose pattern to the target pattern and calculating at least one measure of error representing a fidelity of the predicted process dose pattern to the target pattern, and performing an implant on the workpiece according to the target pattern, the process array, and the spot beam recipe if the at least one measure of error falls below a predetermined error threshold.

A spot beam ion implantation system according to an embodiment of the present disclosure includes an ion source from which ions are extracted and are formed into a spot beam directed at a workpiece holder adapted to hold a workpiece, a scanner which scans the spot beam in a scan direction, and a beam profiler adapted to measure a beam current of the spot beam. The further includes a system controller in communication with the ion source, the scanner, the workpiece holder, and the beam profiler, wherein the system controller is adapted to receive a target pattern and store the target pattern as a target pattern array, analyze the target pattern to identify locations and orientations of maximal gradients in the target pattern, and operate the workpiece holder to rotate the target pattern and the workpiece to align with a spot beam profile and a scan direction of the spot beam, and transpose the target pattern from the target pattern array to a process array. The system controller is further adapted to optimize properties of the process array to better suit the target pattern, calculate a largest possible beam spot size appropriate for reproducing the target pattern, and select a spot beam recipe for optimizing the spot beam to reproduce the target pattern during an implantation process. The system controller is further adapted to operate the ion source, the scanner, and the beam profiler to perform a test scan, wherein the spot beam is generated according to the spot beam recipe and is scanned across the beam profiler to determine a beam sweep angle of the spot beam, and rotating the target pattern, the process array, and the workpiece via the workpiece holder to account for the beam sweep angle. The system controller is further adapted to generate a predicted process dose pattern, compare the predicted process dose pattern to the target pattern and calculate at least one measure of error representing a fidelity of the predicted process dose pattern to the target pattern, and operate the ion source and the scanner to perform an implant on the workpiece according to the target pattern, the process array, and the spot beam recipe if the at least one measure of error falls below a predetermined error threshold.

### BRIEF DESCRIPTION OF THE DRAWINGS

By way of example, various embodiments of the disclosed techniques will now be described, with reference to the accompanying drawings, wherein:

FIG. 1 is a schematic illustration of a spot beam ion implantation system in accordance with the present disclosure;

FIG. 2 is a flow diagram illustrating a method for performing a non-uniform ion implant in accordance with the present disclosure;

FIG. 3 is a diagram illustrating a target pattern and a target pattern array in accordance with the present disclosure;

FIGS. 4A-4D are a series of diagrams illustrating optimization of a target pattern and a process array in accordance with the present disclosure;

FIG. 5 is a diagram illustrating a test scan of a spot beam directed along a horizontal path in accordance with the present disclosure; and

FIG. 6 is a graph illustrating the effect of various optimization steps on measures of error as a function of target pattern orientation.

### DETAILED DESCRIPTION

The present embodiments will now be described more fully hereinafter with reference to the accompanying drawings, wherein some exemplary embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

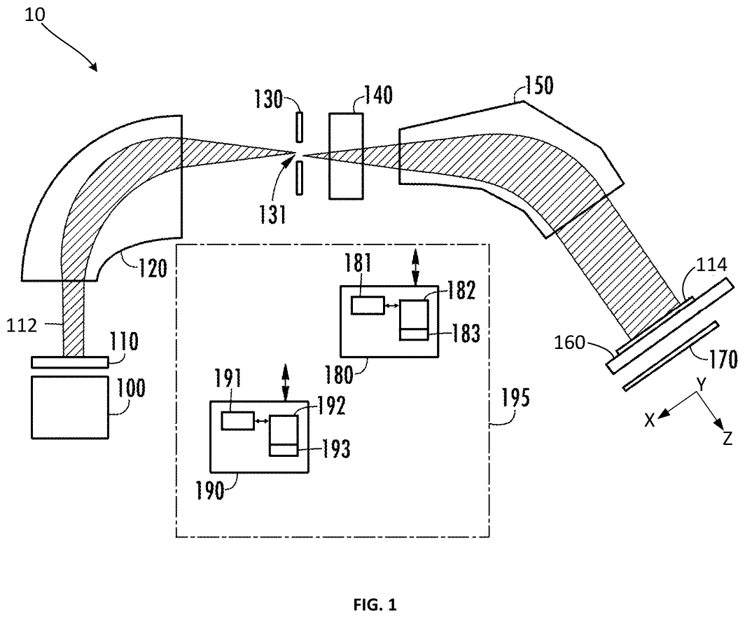

The present embodiments provide methods for performing non-uniform ion implantation in semiconductor workpieces. The non-uniform ion implantation processes of the present disclosure may be performed using any suitable variety of ion implantation system adapted to implant a workpiece using a spot beam. An example of such a spot beam ion implantation system 10 (hereinafter “the system 10”) is schematically illustrated in FIG. 1.

The system 10 may include an ion source 100 having a plurality of chamber walls defining an ion source chamber. In certain embodiments, the ion source 100 may be an RF ion source. In such an embodiment, an RF antenna may be disposed against a dielectric window. The dielectric window may comprise part or all of one of the chamber walls. The RF antenna may be formed of an electrically conductive material, such as copper. An RF power supply may be coupled to the RF antenna and may supply an RF voltage to the RF antenna. In various embodiments, the power supplied by the RF power supply may be between 0.1 and 10 kW and may be any suitable frequency, such as between 1 and 100 MHz. Further, the power supplied by the RF power supply may be pulsed. The present disclosure is not limited in this regard.

In another embodiment, a cathode may be disposed within the ion source chamber. In such an embodiment, a filament may be disposed behind the cathode and may be energized so as to emit electrons. These electrons are attracted to the cathode, which in turn may emit electrons into the ion source chamber. This cathode may be referred to as an indirectly heated cathode (IHC), since the cathode is heated indirectly by the electrons emitted from the filament.

Other embodiments of the ion source 100 are also contemplated. For example, the plasma may be generated in a different manner, such as by a Bernas ion source, a capacitively coupled plasma (CCP) source, a microwave or ECR (electron-cyclotron-resonance) ion source, etc. The manner in which the plasma is generated is not limited by this disclosure.

One chamber wall of the ion source 100, referred to as an extraction plate, may include an extraction aperture. The extraction aperture may be an opening through which ions 112 generated in the ion source chamber are extracted and directed toward a workpiece 114. The extraction aperture may have any suitable shape. In certain embodiments, the extraction aperture may be oval or rectangular shaped, having a first dimension, referred to as the width (e.g., horizontal dimension), which may be significantly larger than a second dimension, referred to as the height (e.g., vertical dimension). The present disclosure is not limited in this regard.

Disposed outside and proximate the extraction aperture of the ion source 100 are extraction optics 110. In certain embodiments, the extraction optics 110 include one or more electrodes. Each electrode may be a single electrically conductive component with an aperture formed therein. Alternatively, each electrode may include two electrically conductive components spaced apart from one another to define an aperture between the two components. The electrodes may be formed of a metal, such as tungsten, molybdenum or titanium. One or more of the electrodes may be electrically connected to ground. In certain embodiments, one or more of the electrodes may be biased using an electrode power supply. The electrode power supply may be used to bias one or more of the electrodes relative to the ion source 100 so as to attract ions through the extraction aperture. The extraction aperture and the aperture in the extraction optics are aligned such that the ions 112 pass through both apertures.

A mass analyzer 120 may be located downstream from the extraction optics 110. The mass analyzer 120 may use magnetic fields to influence and guide the path of the extracted ions 112. The magnetic fields affect the flight path of ions according to their mass and charge. A mass resolving device 130 having a resolving aperture 131 may be disposed at the output, or distal end, of the mass analyzer 120. By proper selection of the magnetic fields, only those ions 112 having a selected mass and charge will be directed through the resolving aperture 131. Other of the ions 112 will strike the mass resolving device 130 or a wall of the mass analyzer 120 and will not travel any further through the system 10. The ions 112 that pass through the mass resolving device 130 may form a spot beam. (i.e., an ion beam having a generally circular cross-sectional shape, further described below).

The spot beam may then enter a scanner 140 located downstream from the mass resolving device 130. The scanner 140 may cause the spot beam to be fanned out into a plurality of divergent beamlets. The scanner 140 may be electrostatic or magnetic. In certain embodiments, a collimator 150 located downstream from the scanner 140 then converts the divergent beamlets into a plurality of parallel beamlets that are directed toward the workpiece 114. In other embodiments, a collimator 150 may not be employed.

The workpiece 114 may be disposed on a movable workpiece holder 160. In certain embodiments, the direction in which the ion beam travels immediately prior to striking the workpiece 114 is referred to as the Z-direction, the direction perpendicular to the Z-direction and horizontal may be referred to as the X-direction, while the direction perpendicular to the Z-direction and vertical may be referred to as the Y-direction. Thus, in the illustrated system 10, it is assumed that the scanner 140 scans the spot beam in the X-direction while the movable workpiece holder 160 is translated in the Y-direction.

The system 10 may further include a beam profiler 170 disposed proximate the workpiece holder 160. The beam profiler 170 may be used to measure certain parameters associated with the spot beam, including beam current as a function a position of the spot beam across a workpiece as well as beam current as a function of position within the spot beam (i.e., beam current across the spot beam profile). The beam profiler 170 may include one or more Faraday devices arranged in a linear manner. In another embodiment, the beam profiler 170 may include a plurality of Faraday devices arranged in a two-dimensional array. The Faraday devices may collect current, and the beam profiler 170 may measure an amount of current collected by each Faraday device.

While the beam profiler 170 is illustrated as being near the workpiece 114, it will be understood that the beam profiler 170 may be disposed in other locations in the system. For example, in one embodiment, the beam profiler 170 may be disposed in the position typically occupied by the workpiece 114 during operation. In this way, the beam profiler 170 may provide feedback that is representative of the current that would be experienced by the workpiece 114 during an implantation process.

A controller 180 may be used to control the system 10. The controller 180 may have a processing unit 181 and an associated memory device 182. The memory device 182 may store instructions 183, which, when executed by the processing unit 181, enable the system 10 to perform various functions described herein. The memory device 182 may be any non-transitory storage medium, including a non-volatile memory, such as a FLASH ROM, an electrically erasable ROM or other suitable devices. In other embodiments, the memory device 182 may be a volatile memory, such as a RAM or DRAM. In certain embodiments, the controller 180 may be a general-purpose computer, an embedded processor, or a specially designed microcontroller. The specific implementation of the controller 180 is not limited by this disclosure.

Further, this disclosure describes the creation and use of various data sets, arrays, and algorithms. In one embodiment, these data sets, arrays, and algorithms may be stored in the memory device 182. In other embodiments, the data sets, arrays, and algorithms may be stored in a second computing unit 190, such as a server or personal computer. The second computing unit 190 may have a processing unit 191 and an associated memory device 192. Various data sets, arrays, and algorithms 193 described herein may be stored in the associated memory device 192 and may be used/executed by the processing unit 191 of the second computing unit 190.

In this disclosure, the controller 180 and the second computing unit 190 are together referred to generically as “the system controller 195.” Throughout this disclosure, and for convenience of description, functions performed by the system controller 195 as described below shall be understood to be a combination of all actions performed by the controller 180 and the second computing unit 190. As stated above, in certain embodiments of the system 10, the second computing unit 190 may be omitted and the controller 180 may perform all of the system control and computational functions described herein. In such embodiments, the system controller 195 may be the same as the controller 180. In other embodiments, some of the computationally intensive tasks of the present disclosure may be performed by the second computing unit 190. Thus, in such embodiments, the system controller 195 is the combination of the controller 180 and the second computing unit 190. This disclosure is not limited to any particular partition of tasks or functions between the controller 180 and the second computing unit 190.

The system controller 195 may be in communication with the ion source 100, the scanner 140, the movable workpiece holder 160, and the beam profiler 170, and may dictate the operation of such components as described in greater detail below.

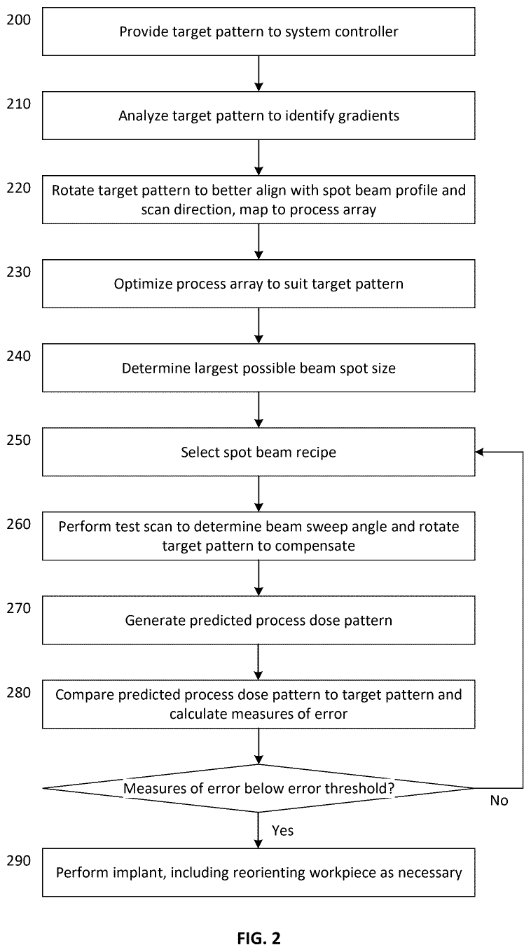

Referring to FIG. 2, a flow diagram illustrating an exemplary method for operating the above-described system 10 to produce a desired, non-uniform ion implant pattern in a workpiece in accordance with the present disclosure is shown. The method will now be described with reference to the flow diagram shown in FIG. 2 as well as the schematic illustration of the system 10 provided in FIG. 1.

At block 200 of the method, a desired non-uniform implant pattern may be provided to the system controller 195. The non-uniform implant pattern may be stored by the system controller 195 (e.g., in the memory device 182 of the controller 180) as a two-dimensional array of data, wherein each element of the array represents an area of the non-uniform implant pattern, and wherein each element in the array has associated values indicating a dose, energy, and species with which the corresponding area of the non-uniform implant pattern should be implanted (i.e., an implant “recipe” for the corresponding area). In various embodiments, each element of the array may represent a rectangle having width and a height corresponding to an area of the non-uniform implant pattern. The present disclosure is not limited in this regard.

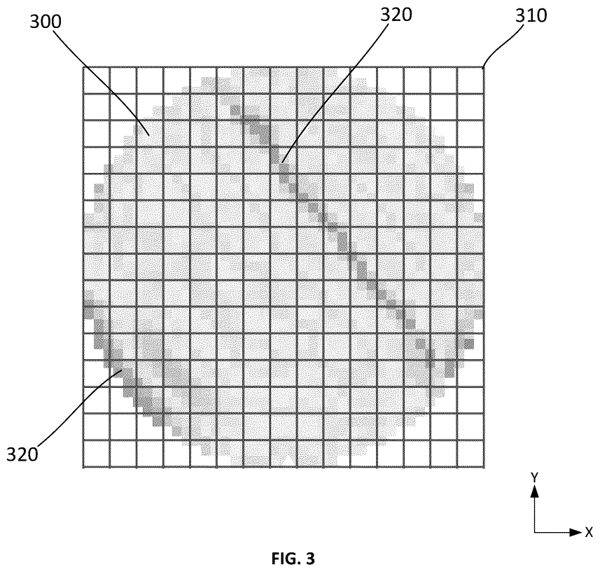

An example of a desired non-uniform implant pattern 300 (hereinafter “the target pattern 300”) is shown in FIG. 3. The target pattern 300 may be provided for implanting a 300 mm diameter workpiece, for example. Again, the target pattern 300 may be stored by the system controller 195 as a two-dimensional array 310, hereinafter referred to as “the target pattern array 310.” For purposes of description and illustration, the target pattern array 310 is shown in FIG. 3 as a 15×15 array, with each element in the array representing a rectangle having a width of 20 mm (measured along the X-axis) and a height of 20 mm (measured along the Y-axis). In practical application, the elements may represent rectangles having significantly smaller dimensions (e.g., 7.5 mm×7.5 mm, 2 mm×2 mm, 1 mm×1 mm, etc.). Furthermore, the elements are not limited to representing squares (as shown in FIG. 3). In some applications, the elements may represent rectangles having unequal heights and widths. The present disclosure is not limited in this regard.

At block 210 of the method, the system controller 195 may analyze the target pattern 300 (as stored in the target pattern array 310) to identify the location and orientation of maximal gradients in the pattern. For example, the target pattern 300 may include a plurality of roughly linear striations 320 indicating areas of the target pattern 300 that are implanted more heavily than adjacent areas of the target pattern 300. In various embodiments, the target pattern 300 may be provided to perform a wafer stress management (WSM) process, wherein a stress management film formed of a material such as silicon nitride, silicon dioxide, various carbon-based materials, etc. disposed on the front side or the back side of a semiconductor wafer is subjected to a non-uniform implant according to the target pattern 300 to introduce or relax mechanical stress in the film in a highly controlled, targeted manner intended to forcibly counteract warping in the semiconductor wafer. This is but one example of an application of a non-uniform implant pattern. Many other applications exist, such as altering the etch rate (wet or dry etch) of a workpiece or altering the chemical metal polishing (CMP) rate of a workpiece. The present disclosure is not limited to any particular application(s).

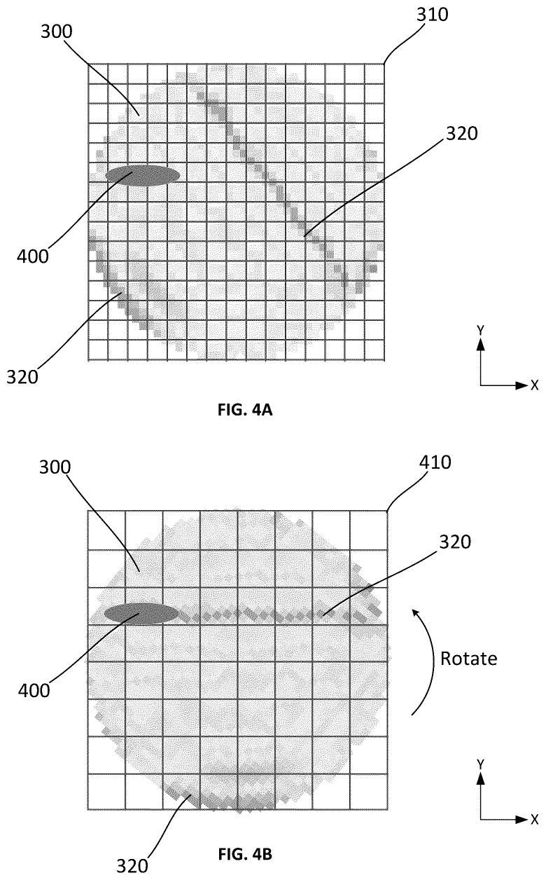

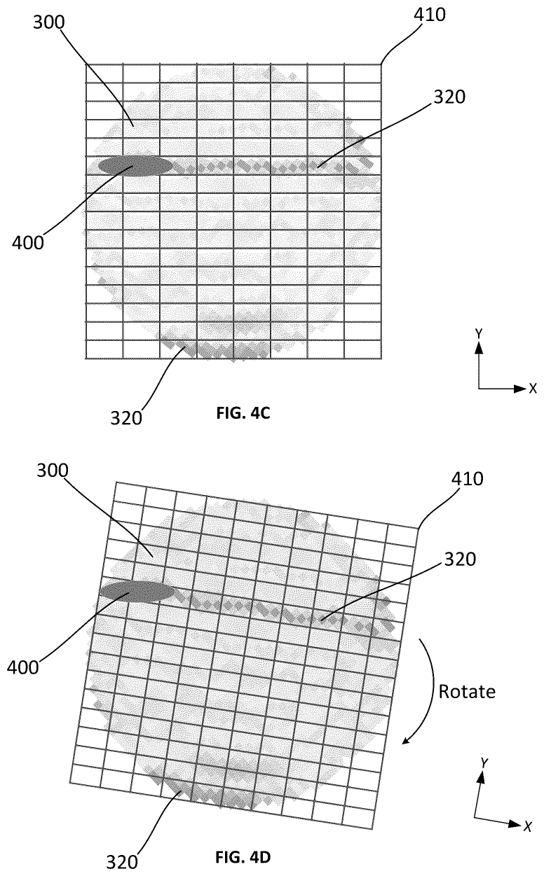

At block 220 of the method shown in FIG. 2, the system controller 195 may rotate the target pattern 300 to better align with an available or preferred spot beam profile and a spot beam scan direction. The system controller 195 and may also transpose the target pattern 300 from the target pattern array 310 to a process array that corresponds to the process capabilities of the system 10 and that will eventually dictate the implantation of the workpiece 114. For example, referring to FIG. 4A, an available or preferred spot beam profile 400 (hereinafter “the spot beam profile 400”) is shown superposed on the target pattern 300 described above. The spot beam profile 400 may have a horizontally elongated, ellipsoid shape (i.e., an ellipsoid having a width along the X-axis that is greater than a height along the Y-axis). Moreover, during an implant process, the spot beam profile 400 may be scanned horizontally across a workpiece as described above. However, the striations 320 of the target pattern 300 are oriented at an angle of roughly 55 degrees relative to horizontal. Thus, in order to better align the target pattern 300 with the spot beam profile 400 and the scan direction, the system controller 195 may rotate the target pattern 300 55 degrees counterclockwise so that the striations 320 are oriented generally horizontally as shown in FIG. 4B. This will of course require a corresponding, physical rotation of the workpiece 114 (via rotation of the workpiece holder 160 at the direction of the system controller 195) by a corresponding amount when implantation of the workpiece 114 is ultimately performed (as further described below) since the target pattern 300 maps directly to features of the workpiece 114 that are to be implanted. Said another way, the target pattern and the workpiece 114 may be rotated to orient one or more of the striations 320 closer to parallel with at least one of the scan direction and the direction in which the spot beam profile 400 is elongated. After the above-described rotation is performed, a height of the horizontally elongated spot beam profile 400 may be roughly similar to the heights of the horizontally oriented striations 320 (as further described below). Thus, when a spot beam having the spot beam profile 400 is scanned horizontally across a workpiece during an implant process, the striations 320 of the target pattern 300 may be reproduced more accurately and more efficiently than if the target pattern 300 was not rotated to better align with the spot beam profile 400 and the horizontal scan direction.

As also shown in FIG. 4B, the rotated target pattern 300 may be transposed to a process array 410 that corresponds to the process capabilities of the system 10 and that will dictate an actual implant process executed by the system 10. Like the target pattern array 310, the process array 410 is stored by the system controller 195 as a two-dimensional array of data. Each element of the process array 410 may represent an area of the workpiece 114 to be implanted, and each element in the process array 410 may have associated values indicating a dose, energy, and species with which the corresponding area of the workpiece 114 should be implanted (i.e., an implant “recipe” for the corresponding area). In various embodiments, each element of the process array 410 may represent a rectangle having width and a height corresponding to an area of the workpiece 114 to be implanted. The present disclosure is not limited in this regard.

The dimensions of the elements in the process array 410 may differ from those of the elements in the target pattern array 310 (depending on the process capabilities of the system 10 and various other parameters). For example, while each element of the target pattern array 310 (see FIG. 4A) represents a rectangle having a width of 20 mm and a height of 20 mm, each element of the process array 410 may represent a rectangle having a width of 37.5 mm and a height of 37.5 mm. The present disclosure is not limited in this regard, and, in various embodiments, the dimensions may vary from those stated in width and/or height.

It will be understood that the horizontally elongated spot beam profile 400, the horizontal scan direction of the spot beam, and the striated target pattern 300 described above are provided by way of example for purposes of description. Those of skill in the art will appreciate that many other spot beam profiles are possible (e.g., vertically elongated, irregular, etc.), that the scan direction of the spot beam may be vertical instead of horizontal, and that many other desired implant patterns are possible. Regardless of the particular spot beam profile, scan direction, and desired implant pattern implemented in a particular application, the system controller 195 may rotate a target pattern and a workpiece to better align with a spot beam profile and a scan direction in the manner described above.

At block 230 of the method shown in FIG. 2, the system controller 195 may optimize properties of the process array 410 to better suit the target pattern 300. This may include modifying the dimensions of the areas (e.g., rectangular areas) represented by the elements of the process array 410, as well as shifting the process array 410 relative to the target pattern 300, to better fit the features in the target pattern 300. For example, as described above and as shown in FIG. 4B, each element of the process array 410 may represent a square having a width of 20 mm and a height of 20 mm. However, the rotated target pattern 300 includes horizontally oriented striations 320, meaning that the rotated target pattern 300 exhibits a greater amount of variability in the vertical direction (i.e., along the Y-axis) than in the horizontal direction (i.e., along the X-axis). In some cases, a single element of the process array 410 (i.e., a single square of the process array 410) may encompass significant variations in the target pattern 300 in the vertical direction. However, since each element in the process array 410 is associated with only a single target dose value, an implant process performed in accordance with the process array 410 may produce an imprecise implant pattern (i.e., relative to the target pattern 300) that does not fully capture such variations. Thus, in order to improve the precision of the process array 410 to achieve better fidelity with respect to the target pattern 300, the dimensions of the rectangles represented by the elements of the process array 410 may be adjusted to provide greater granularity in the vertical direction. For example, referring to FIG. 4C, the system controller 195 may shorten the rectangles represented by the elements of the process array 410 while maintaining the widths of the rectangles, thus increasing the number of elements in the process array 410 in the vertical direction. By increasing the granularity of the process array 410 in the vertical direction thusly, the occurrence of significant variations in the target pattern 300 being encompassed by a single rectangle of the process array 410 is greatly reduced, thus improving the precision of the process array 410 and the fidelity to the target pattern 300. Fidelity and precision may be further improved by shifting the process array 410 vertically (i.e., along the Y-axis) and/or horizontally (i.e., along the X-axis) relative to the target pattern 300 to better align the variations in the target pattern 300 with the elements of the process array 410.

At block 240 of the method shown in FIG. 2, the system controller 195 may calculate a largest “beam spot size” possible for producing the target pattern 300. The term “beam spot size” shall be used herein to generically refer to one or more dimensions of a spot beam profile, including, and not limited to, a height, width, or diameter of a spot beam profile. A largest possible beam spot size is desirable because it typically reduces the processing time of a workpiece and thereby increases workpiece throughput. A large beam spot size also reduces “stitching patterns” that are associated with smaller beam spot sizes. For example, referring again to FIG. 4C, the system controller 195 may determine that a maximum height of the spot beam profile 400 should be equal to a height of a thinnest (i.e., shortest along the Y-axis) of the striations 320 in order to accurately and efficiently reproduce such thinnest striation when a spot beam having the spot beam profile 400 is scanned across a workpiece during an implant process. By contrast, if a spot beam profile having a height greater than that of the thinnest striation were used, the spot beam profile would produce a striation on a workpiece that would be thicker (i.e., taller) than the thinnest striation of the target pattern 300, thus resulting in an undesirable deviation from the target pattern 300. Conversely, if a spot beam profile having a height significantly less than that of the thinnest striation were used, the spot beam profile would have to be scanned across a workpiece many times (with the workpiece being translated vertically between scans) in order to produce a striation having a cumulative thickness (i.e., height) equal to a thickness of the thinnest striation of the target pattern 300. Moreover, a smaller spot beam profile would have a lower total beam current, meaning that the spot beam profile would have to dwell on a workpiece for a longer period of time (i.e., compared to a larger spot beam profile) to achieve a desired dose. This would increase the processing time of the workpiece and thereby decrease workpiece throughput.

At block 250 of the method shown in FIG. 2, the system controller 195 may select a “spot beam recipe” (also referred to as a “process recipe”) for producing an optimal spot beam adapted to reproduce the target pattern 300 during an implantation process. This selection may be based on various desired properties of the spot beam, including, and not limited to, species to be implanted, beam uniformity, beam current, current density, beam angle/orientation, damage per ion to achieve desired material modification, beam spot centroid characteristics, and the beam spot size calculated at block 240 of the method (described above). The recipe may be selected from a table or database of recipes stored in the system controller 195 (e.g., in the memory device 182 of the controller 180).

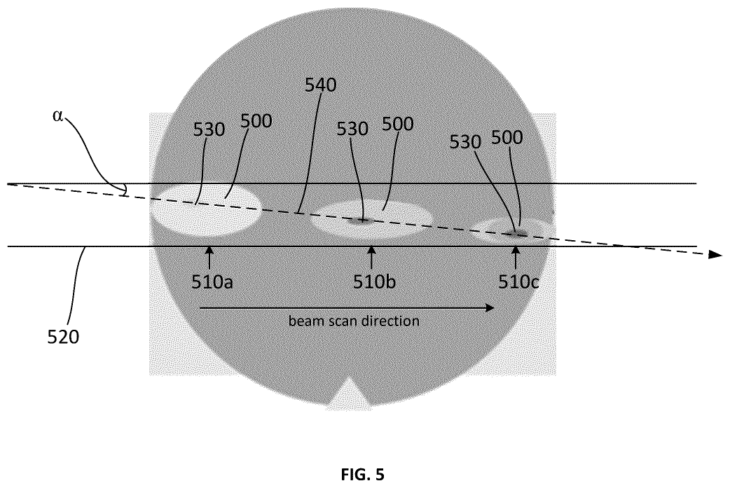

At block 260 of the method shown in FIG. 2, the system controller 195 may operate the system 10 to perform a “test scan,” wherein a spot beam is generated according to the spot beam recipe selected in block 250 of the method described above and is scanned across the beam profiler 170 of the system 10 along a beam path having a length that equals or approximates the width of a workpiece to be implanted (e.g., 300 mm). In various embodiments, and depending on the configuration of the beam profiler 170, the beam profiler 170 may measure the beam current profile of the spot beam at several discrete locations along the beam path. For example, referring to FIG. 5, system 10 may generate a spot beam 500 and the beam profiler 170 (not shown in FIG. 5) may measure a beam current profile of the spot beam 500 at three location 510a, 510b, 510c as the spot beam 500 is scanned horizontally along a path 520.

Ideally, the beam current profile measured at each of the locations 510a, 510b, 510c would be identical. However, due to variations in system equipment, such as may result from imperfections in the magnet of the scanner 140 and/or miscalibration of the scanner 140, the beam current profile of the spot beam 500 may vary as the spot beam 500 is scanned along the path 520. For example, as shown in FIG. 5, the area of the beam current (i.e., the size of the spot) may progressively shorten or flatten as the spot beam 500 moves across the three locations 510a, 510b, 510c. Additionally, a centroid 530 of the spot beam 500 may progressively shift downwardly within the spot beam 500 as the spot beam 500 moves across the three locations 510a, 510b, 510c. The term “centroid” is defined herein to mean a portion of a spot beam where beam current is most concentrated, which may or may not be at the geometric center of the spot.

The cumulative effect of the above-described variations in the profile of the spot beam 500 is that, while the spot beam 500 is scanned horizontally along the path 520, the beam current profile of the spot beam is actually distributed along an “effective path” 540 that is oriented at a non-zero angle α relative to horizontal, hereinafter referred to as “the beam sweep angle α.” In the example shown in FIG. 5, the beam sweep angle α may have a value of 6 degrees. Of course, the beam sweep angle α may vary depending on a particular application and on the particular implantation tool used. The present disclosure is not limited in this regard. Moreover, while FIG. 5 depicts the beam current profile being measured at three locations 510a, 510b, 510c, alternative embodiments are contemplated wherein the beam current profile is measured at a greater number of locations (e.g., 5, 7, or more locations). Regardless of the number of locations where the beam current profile is actually measured by the beam profiler 170, the system controller 195 may extrapolate the measured beam current profiles to a number of locations (e.g., 20, 30, 40 or more) covering the entire path 520, and may use such extrapolation to accurately determine the beam sweep angle α. Alternatively, if the beam profiler 170 of the system 10 is sufficiently robust (e.g., if an array of Faraday cups in the beam profiler 170 is large enough and dense enough), the beam profiler 170 may measure the actual beam current profile along the entire path 520 and may determine the beam sweep angle α from such measurement.

When a conventional spot beam ion implantation system generates a spot beam exhibiting a non-zero beam sweep angle, the system is typically taken offline and the components of the system causing the non-zero beam sweep angle are adjusted, cleaned, calibrated, repaired, etc. to make the beam sweep angle zero or near zero. This may result in significant tool downtime that decreases the throughput of the system. However, in the system and method of the present disclosure, the system controller 195 may avoid such downtime by reorienting the target pattern 300, the process array 410, and the workpiece 114 to account for the calculated beam sweep angle α. In various embodiments, such reorientation may be performed as a further optimization or refinement of the adjustments to the target pattern 300, the process array 410, and the orientation of the workpiece 114 performed in blocks 220 and 230 described above and shown in FIGS. 4B and 4C. For example, referring to FIG. 4D, the system controller 195 may rotate the target pattern 300 and the process array 410 (relative to the orientation of the target pattern 300 and the process array 410 shown in FIG. 4C) 6 degrees clockwise to account for the calculated beam sweep angle α of 6 degrees shown in FIG. 5. This will of course require a corresponding, physical rotation of the workpiece 114 (via rotation of the workpiece holder 160 at the direction of the system controller 195) by a corresponding amount when implantation of the workpiece 114 is ultimately performed as further described below) since the target pattern 300 maps directly to features of the workpiece 114 that are to be implanted. When the target pattern 300, process array 410, and workpiece 114 are rotated thusly, the striations 320 in the target pattern 300 may be oriented at an angle of about 6 degrees relative to horizontal. Thus, when the spot beam 500 is scanned horizontally across the workpiece 114 to reproduce the target pattern 300, the spot beam 500 may distribute ions along an angled effective path across the workpiece 114 that is suitable for reproducing the angled striations of the target pattern 300 in the workpiece 114.

As described above with respect to block 260 of the method, the system controller 195 extrapolates a complete horizontal scan of the spot beam 500 along the effective path 540 to calculate the beam sweep angle α. At block 270 of the method, the system controller 195 may convolve the extrapolated horizontal scan from block 260 with the scan direction of the workpiece 114 (e.g., the vertical direction) to generate a prediction or model of an implant that will be performed on the workpiece 114. This prediction, hereinafter referred to as “the predicted process dose pattern,” may be generated according to the optimized orientation of the target pattern 300, process array 410, and workpiece 114 acquired from blocks 220, 230, and 260 of the method described above, as well as the spot beam recipe selected in block 250 of the method described above. The predicted process dose pattern may be stored by the system controller 195 as a two-dimensional array, hereinafter referred to as “the predicted process dose pattern array.” The predicted process dose pattern array may have the same number of elements and the same dimensions as the process array 410.

At block 280 of the method shown in FIG. 2, the system controller 195 may compare the predicted process dose pattern to the target pattern 300 to calculate one or more “measures of error” representing the fidelity of the predicted process dose pattern to the target pattern 300. These measures of error may include, and are not limited to, root mean square error (percent dose), percent of array elements having an error greater than a predetermined value, range dose error (percent), etc. If the measures of error exceed a predetermined threshold, hereinafter referred to as “the error threshold” (which may correlate to a minimum acceptable device yield) the system controller 195 may return to block 250 of the method described above and may select a different spot beam recipe that may better fit the target pattern 300. This selection may be based on differences between the predicted process dose pattern and the target pattern 300. In various embodiments, the newly selected spot beam recipe may define a spot beam having a reduced beam spot size and/or an increased beam current density profile which may improve fidelity to the target pattern 300. The system controller 195 may perform blocks 250 through 270 of the method in an iterative manner until the measures of error are below the error threshold.

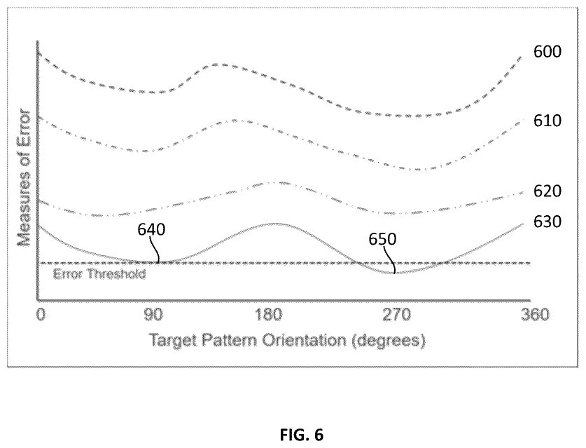

Referring to FIG. 6, a graph is shown illustrating the effect of the optimization steps described above on the measures of error as a function of target pattern orientation. As depicted on the graph, the optimization steps include rotating the target pattern 300 and the workpiece 114 to better align with the spot beam profile (as indicated by the line 600), rotating the target pattern 300, the process array 410, and the workpiece 114 to account for the calculated beam sweep angle α (as indicated by line 610), modifying and/or shifting the process array 410 to provide a better fit with the target pattern 300 (as indicated by line 620), and tuning the spot beam recipe to improve fidelity to the target pattern 300 (as indicated by line 630). Each of these optimization steps may contribute to driving the measures of error below the error threshold. Once the system controller 195 achieves a predicted process dose pattern having measures of error below the error threshold, the system controller 195 may, at block 290 of the method, operate the system 10 to perform an implant on the workpiece 114 according to the optimized target pattern 300, process array 410, and spot beam recipe, including rotating the workpiece 114 (via rotation of the workpiece holder 160) in accordance with the rotation of the target patten 300 performed in block 220 of the method and the rotation of the target pattern 300 and the process array 410 performed in block 260 of the method. If the system controller 195 determines that numerous orientations of the target pattern 300 achieve or fall below the error threshold (as indicated at 640 and 650 in the graph), the system controller 195 may select the most optimal of the orientations (i.e., the orientation corresponding to the lowest measures of error; 650 in the depicted graph) for performing the implant.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A method of producing a non-uniform ion implant in a workpiece, the method comprising:
providing a target pattern to a system controller of a spot beam ion implantation system, wherein the system controller stores the target pattern as a target pattern array;
analyzing the target pattern to identify locations and orientations of maximal gradients in the target pattern;
rotating the target pattern and the workpiece to align with a spot beam profile and a scan direction, and transposing the target pattern from the target pattern array to a process array;
optimizing properties of the process array to better suit the target pattern;
calculating a largest possible beam spot size appropriate for reproducing the target pattern;
selecting a spot beam recipe for producing an optimal spot beam adapted to reproduce the target pattern during an implantation process;
performing a test scan, wherein a spot beam is generated according to the spot beam recipe and is scanned across a beam profiler of the spot beam ion implantation system to determine a beam sweep angle of the spot beam, and rotating the target pattern, the process array, and the workpiece to account for the beam sweep angle;
generating a predicted process dose pattern;
comparing the predicted process dose pattern to the target pattern and calculating at least one measure of error representing a fidelity of the predicted process dose pattern to the target pattern; and
performing an implant on the workpiece according to the target pattern, the process array, and the spot beam recipe if the at least one measure of error falls below a predetermined error threshold.

2. The method of claim 1, wherein each element of the target pattern array represents an area of the target pattern, and wherein each element in the target pattern array has associated values indicating at least one of a dose, energy, and species with which a corresponding area of the target pattern should be implanted.

3. The method of claim 1, wherein rotating the target pattern and the workpiece to align with the spot beam profile and the scan direction comprises orientating one or more striations in the target pattern closer to parallel with at least one of the scan direction and a direction in which the spot beam profile is elongated.

4. The method of claim 1, wherein the process array is stored in the system controller, wherein each element in the process array represents an area of the workpiece, and wherein each element in the process array has associated values indicating at least one of a dose, energy, and species with which the corresponding area of the workpiece should be implanted.

5. The method of claim 1, wherein optimizing properties of the process array to better suit the target pattern comprises at least one of modifying dimensions of areas represented by elements of the process array and shifting the process array relative to the target pattern.

6. The method of claim 1, wherein selecting the spot beam recipe for producing an optimal spot beam adapted to reproduce the target pattern during an implantation process comprises considering one or more of a species to be implanted, beam uniformity, beam uniformity, beam current, current density, beam angle/orientation, damage per ion to achieve desired material modification, beam spot centroid characteristics, and beam spot size, and selecting the spot beam recipe from a database of recipes stored in the system controller.

7. The method of claim 1, wherein performing the test scan comprises measuring a beam current profile of the spot beam at a number of discrete locations along a beam path of the spot beam and extrapolating the measured beam current profiles to calculate a complete scan of the spot beam.

8. The method of claim 7, wherein generating the predicted process dose pattern comprises convolving the extrapolated, complete scan of the spot beam with a scan direction of the workpiece to generate a prediction of an implant that will be performed on the workpiece.

9. The method of claim 1, wherein the at least one measure of error includes at least one of a root mean square error, a percent of array elements having an error greater than a predetermined value, and a range dose error.

10. The method of claim 1, wherein, if the at least one measure of error exceeds the predetermined error threshold, the method further comprises selecting a new spot beam recipe defining a new spot beam having at least one of a reduced beam spot size and an increased beam current density profile relative to the previously selected spot beam recipe.

11. A spot beam ion implantation system, comprising:
an ion source from which ions are extracted and are formed into a spot beam directed at a workpiece holder adapted to hold a workpiece;
a scanner which scans the spot beam in a scan direction;
a beam profiler adapted to measure a beam current of the spot beam; and
a system controller in communication with the ion source, the scanner, the workpiece holder, and the beam profiler, wherein the system controller is adapted to:
receive a target pattern and store the target pattern as a target pattern array;
analyze the target pattern to identify locations and orientations of maximal gradients in the target pattern;
operate the workpiece holder to rotate the target pattern and the workpiece to align with a spot beam profile and a scan direction of the spot beam, and transpose the target pattern from the target pattern array to a process array;
optimize properties of the process array to better suit the target pattern;
calculate a largest possible beam spot size appropriate for reproducing the target pattern;
select a spot beam recipe for optimizing the spot beam to reproduce the target pattern during an implantation process;
operate the ion source, the scanner, and the beam profiler to perform a test scan, wherein the spot beam is generated according to the spot beam recipe and is scanned across the beam profiler to determine a beam sweep angle of the spot beam, and rotating the target pattern, the process array, and the workpiece via the workpiece holder to account for the beam sweep angle;
generate a predicted process dose pattern;
compare the predicted process dose pattern to the target pattern and calculate at least one measure of error representing a fidelity of the predicted process dose pattern to the target pattern; and
operate the ion source and the scanner to perform an implant on the workpiece according to the target pattern, the process array, and the spot beam recipe if the at least one measure of error falls below a predetermined error threshold.

12. The spot beam ion implantation system of claim 11, wherein each element of the target pattern array represents an area of the target pattern, and wherein each element in the target pattern array has associated values indicating at least one of a dose, energy, and species with which a corresponding area of the target pattern should be implanted.

13. The spot beam ion implantation system of claim 11, wherein rotating the target pattern and the workpiece to align with the spot beam profile and the scan direction comprises orientating one or more striations in the target pattern closer to parallel with at least one of the scan direction and a direction in which the spot beam profile is elongated.

14. The spot beam ion implantation system of claim 11, wherein the process array is stored in the system controller, wherein each element in the process array represents an area of the workpiece, and wherein each element in the process array has associated values indicating at least one of a dose, energy, and species with which the corresponding area of the workpiece should be implanted.

15. The spot beam ion implantation system of claim 11, wherein optimizing properties of the process array to better suit the target pattern comprises at least one of modifying dimensions of areas represented by elements of the process array and shifting the process array relative to the target pattern.

16. The spot beam ion implantation system of claim 11, wherein selecting the spot beam recipe for producing an optimal spot beam adapted to reproduce the target pattern during an implantation process comprises considering one or more of a species to be implanted, beam uniformity, beam current, current density, beam angle/orientation, damage per ion to achieve desired material modification, beam spot centroid characteristics, and beam spot size, and selecting the spot beam recipe from a database of recipes stored in the system controller.

17. The spot beam ion implantation system of claim 11, wherein performing the test scan comprises measuring a beam current profile of the spot beam at a number of discrete locations along a beam path of the spot beam and extrapolating the measured beam current profiles to calculate a complete scan of the spot beam.

18. The spot beam ion implantation system of claim 17, wherein generating the predicted process dose pattern comprises convolving the extrapolated, complete scan of the spot beam with a scan direction of the workpiece to generate a prediction of an implant that will be performed on the workpiece.

19. The spot beam ion implantation system of claim 11, wherein the at least one measure of error includes at least one of a root mean square error, a percent of array elements having an error greater than a predetermined value, and a range dose error.

20. The spot beam ion implantation system of claim 11, wherein, if the at least one measure of error exceeds the predetermined error threshold, the system controller is further adapted to select a new spot beam recipe defining a new spot beam having at least one of a reduced beam spot size and an increased beam current density profile relative to the previously selected spot beam recipe.
